(19) United States
(12) Patent Application Publication
(10) Pub. No.: US 2024/0112924 A1
(43) Pub. Date: Apr. 4, 2024

(54) INTEGRATED CIRCUIT PACKAGES AND METHODS

(71) Applicant: Taiwan Semiconductor Manufacturing Co., Ltd., Hsinchu (TW)

(72) Inventors: Hsu-Hsien Chen, Hsinchu (TW); Chen-Shien Chen, Zhubei City (TW); Ting Hao Kuo, Hsinchu (TW); Chi-Yen Lin, Tainan City (TW); Yu-Chih Huang, Hsinchu (TW)

(21) Appl. No.: 18/150,256

(22) Filed: Jan. 5, 2023

Related U.S. Application Data
(60) Provisional application No. 63/377,953, filed on Sep. 30, 2022.

(51) Int. Cl. H01L 21/56; H01L 21/306; H01L 21/768; H01L 21/78; H01L 23/522; H01L 23/538

(52) U.S. Cl. CPC H01L 21/563; H01L 21/30604; H01L 21/76802; H01L 21/78; H01L 23/5226; H01L 23/5389

(57) ABSTRACT

An integrated circuit package including integrated circuit dies with slanted sidewalls and a method of forming are provided. The integrated circuit package may include a first integrated circuit die, a first gap-fill dielectric layer around the first integrated circuit die, a second integrated circuit die underneath the first integrated circuit die, and a second gap-fill dielectric layer around the second integrated circuit die. The first integrated circuit die may include a first substrate, wherein a first angle is between a first sidewall of the first substrate and a bottom surface of the first substrate, and a first interconnect structure on the bottom surface of the first substrate, wherein a second angle is between a first sidewall of the first interconnect structure and the bottom surface of the first substrate. The first angle may be larger than the second angle.

### PRIORITY

This application claims the benefit of U.S. Provisional Application No. 63/377,953, filed on Sep. 30, 2022, entitled “Integrated Circuit Packages and Methods,” which application is hereby incorporated by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3A, 3B, 3C, 4, 5, 6 illustrate various views of intermediate steps during a process for forming an integrated circuit die, in accordance with some embodiments.

FIGS. 7A, 7B, and 7C illustrate various views of an integrated circuit die, in accordance with some embodiments.

FIGS. 8, 9, 10, 11, 12A, 12B, 12C, 13, 14, 15, 16, 17, 18A, 18B, and 18C illustrate various views of intermediate steps during a process for forming an integrated circuit package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, an integrated circuit package comprises an integrated circuit die in one tier as well as another integrated circuit die and an inactive die in another tier. Gap-fill dielectrics are formed around the integrated circuit dies and the inactive die. The integrated circuit dies and the inactive dies are singulated by a plasma dicing process prior to being packaged in the integrated circuit package. The plasma dicing process results in the integrated circuit dies and the inactive die having substantially vertical, smooth, continuous sidewalls, which reduces the risk of delamination of the gap-fill dielectric around the integrated circuit dies and the inactive die during the manufacturing and operation of the integrated circuit package, thereby improving the reliability of the integrated circuit package.

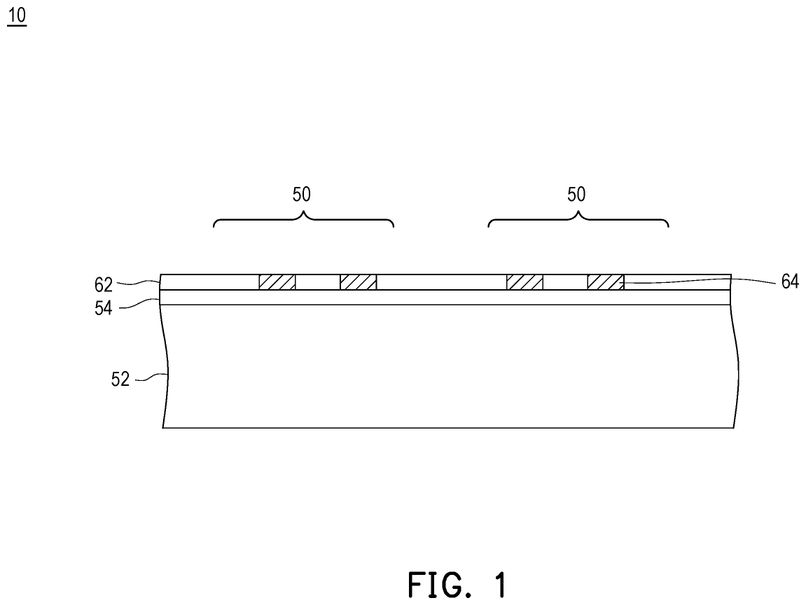

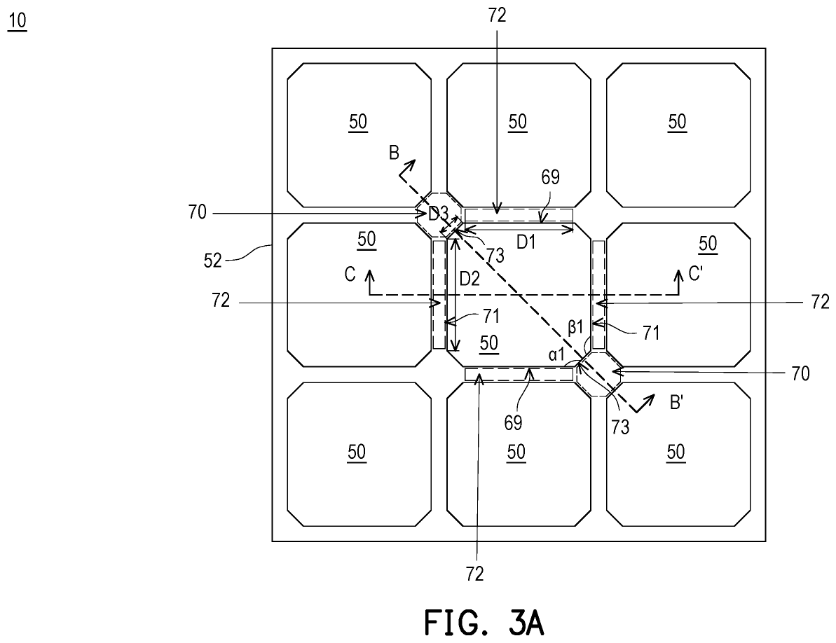

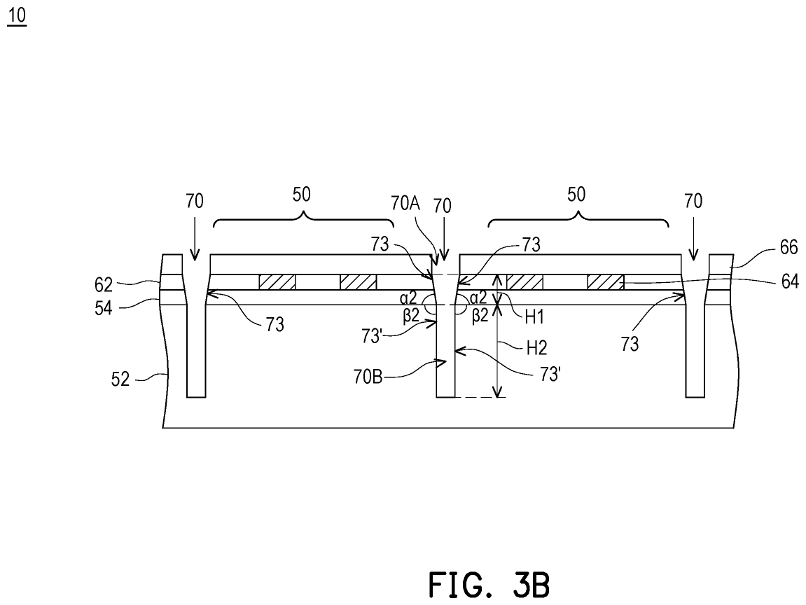

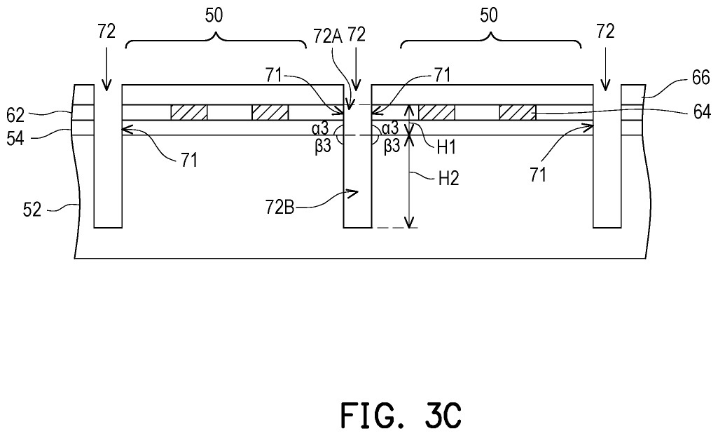

FIGS. 1 through 6 are views of intermediate stages in the manufacturing of integrated circuit dies 50, in accordance with some embodiments. FIG. 3A is a top-down view. FIGS. 1, 2, 3B, 4, 5, and 6 are cross-sectional views shown along respective reference cross-sections B-B′ in the top-down view. FIG. 3C is a cross-sectional view shown along respective reference cross-sections C-C′ in the top-down view.

In FIG. 1, a cross-sectional view of a wafer 10 is illustrated. The wafer 10 comprises integrated circuit dies 50, and the wafer 10 will be subsequently singulated to form discrete integrated circuit dies 50. Each of the integrated circuit dies 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The wafer 10 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1), sometimes called a front side, and an inactive surface (e.g., the surface facing downwards in FIG. 1), sometimes called a back side.

Devices (not separately illustrated) are disposed at the active surface of the semiconductor substrate 52. The devices may be active devices (e.g., transistors, diodes, etc.), capacitors, resistors, etc. An interconnect structure 54 is disposed over the active surface of the semiconductor substrate 52. The interconnect structure 54 interconnects the devices to form an integrated circuit. The interconnect structure 54 may be formed of, for example, metallization patterns in dielectric layers. The dielectric layers may be, e.g., low-k dielectric layers. The metallization patterns include metal lines and vias, which may be formed in the dielectric layers by a damascene process, such as a single damascene process, a dual damascene process, or the like. The metallization patterns may be formed of a suitable conductive material, such as copper, tungsten, aluminum, silver, gold, a combination thereof, or the like. The metallization patterns are electrically coupled to the devices.

A dielectric layer 62 is over the interconnect structure 54, at the front side of the integrated circuit dies 50. The dielectric layer 62 may be formed of an oxide such as silicon oxide, phosphosilicate glass (PSG), borosilicate glass (BSG), boron-doped phosphosilicate glass (BPSG), a tetraethyl orthosilicate (TEOS) based oxide, or the like; a nitride such as silicon nitride or the like; a polymer such as polybenzoxazole (PBO), polyimide, a BCB-based polymer, or the like; a combination thereof; or the like. The dielectric layer 62 may be formed, for example, by chemical vapor deposition (CVD), spin coating, lamination, or the like. In some embodiments, the dielectric layer 62 is formed of TEOS-based silicon oxide. Optionally, one or more passivation layer(s) (not separately illustrated) are disposed between the dielectric layer 62 and the interconnect structure 54.

Die connectors 64 extend through the dielectric layer 62. The die connectors 64 may include conductive pillars, pads, or the like, to which external connections can be made. In some embodiments, the die connectors 64 include bond pads at the front side of the integrated circuit die 50, and include bond pad vias that connect the bond pads to the upper metallization pattern of the interconnect structure 54. In such embodiments, the die connectors 64 (including the bond pads and the bond pad vias) may be formed by a damascene process, such as a single damascene process, a dual damascene process, or the like. The die connectors 64 can be formed of a conductive material, such as a metal, such as copper, aluminum, or the like, which can be formed by, for example, plating, or the like.

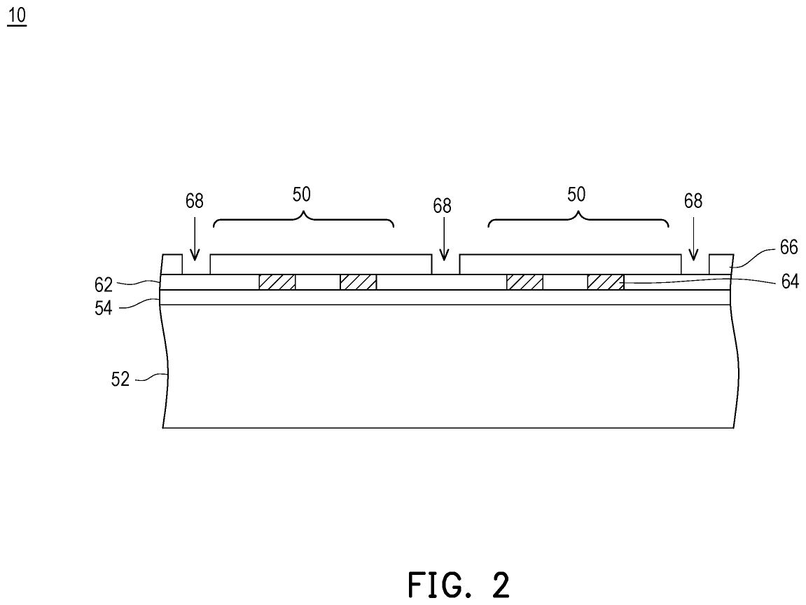

In FIG. 2, a mask 66 is formed over the wafer 10, such as over the dielectric layer 62 and the die connectors 64. The mask 66 may be a photoresist and may be formed by spin coating or the like. The mask 66 may be patterned using suitable photolithography techniques to form openings 68 in the mask 66 that expose portions of the dielectric layer 62. As an example of patterning the mask 66, a mask layer may be formed, and then a photomask may be disposed over the mask layer. The mask layer may then be exposed to a radiation such as ultraviolet (UV) light, excimer laser, or the like, while the photomask masks portions of the mask layer. A baking or curing process may be performed to harden the mask layer. A developer may be used to remove either the exposed or unexposed portions of the mask layer depending on whether a positive or negative photoresist is used, which results in a patterned mask 66 with openings 68. In some embodiments, an optical proximity correction (OPC) technique is used to optimize the photomask design in order to compensate for patterning errors due to light diffraction or other process effects during the patterning process. As a result, the resolution and accuracy of the resulting pattern in the mask 66 is improved.

In FIGS. 3A through 3C, a dicing process is performed to form openings 70 and openings 72 through the portions of the wafer 10 exposed by the mask 66. The mask 66 is omitted in FIG. 3A for illustrative purposes. Although they are described separately, it should be appreciated that the openings 70 and openings 72 may be different portions of a same opening that extends around each of the integrated circuit dies 50 of the wafer 10 in a top-down view. In some embodiments, dry etching with a plasma is used as the dicing mechanism. Plasma dicing is able to form openings with substantially vertical, smooth, and continuous sidewalls, which are also the sidewalls of integrated circuit dies that are subsequently singulated from the wafer 10. As a result, the reliability of an integrated circuit package containing the integrated circuit dies may be improved, as discussed in greater detail below.

In FIG. 3A, a top-down view of a portion of the wafer 10 is shown. The shape of the integrated circuit dies 50 in the top-down view may be an octagon after the dicing process, which may help to reduce the stress in the corners of the integrated circuit dies 50, thereby reducing the risk of cracking in the corners of the integrated circuit dies 50. FIG. 3A illustrates the shape of the integrated circuit dies 50 as an octagon as an example; other shapes are contemplated. Each integrated circuit die 50 comprises first main sidewalls 69, which extend in a first direction (e.g., horizontal) in the top-down view, second main sidewalls 71, which extend in a second direction (e.g., vertical) in the top-down view, and chamfered sidewalls 73, which connect each first main sidewall 69 to a neighboring second main sidewall 71. As a result, each chamfered sidewall 73 abuts (or adjoins) a first main sidewall 69 on one side and a second main sidewall 71 on another side, such that the chamfered sidewall 73 extends between the first main sidewall 69 and the second main sidewall 71. An obtuse angle α1 between a first main sidewall 69 and a neighboring chamfered sidewall 73 is in a range from 130° to 140°. An obtuse angle β1 between a second main sidewall 71 and a neighboring chamfered sidewall 73 is in a range from 130° to 140°. Each first main sidewall 69 may have a length D1 in a range from 1 μm to 30 mm in the top-down view. Each second main sidewall 71 may have a length D2 in a range from 1 μm to 30 mm in the top-down view. Each chamfered sidewall 73 may have a length D3 in a range from 1 μm to 300 μm in the top-down view. The length D1 and the length D2 may be equal. The length D1 and the length D2 may be larger than the length D3. Each opening 70 is disposed among four chamfered sidewalls 73 of four neighboring integrated circuit dies 50. Each opening 72 is disposed between two first main sidewalls 69 of two neighboring integrated circuit dies 50 or between two second main sidewalls 71 of two neighboring integrated circuit dies 50. Two openings 70 and four openings 72 are shown in dotted lines in FIG. 3A for illustrative purposes.

The dicing process may be done in two steps, which forms two respective segments of each opening 70 and each opening 72. In FIG. 3B, each opening 70 comprises an upper segment 70A, which extends through the dielectric layer 62 and the interconnect structure 54, and a lower segment 70B which extends into the semiconductor substrate 52. In FIG. 3C, each opening 72 comprises an upper segment 72A, which extends through the dielectric layer 62 and the interconnect structure 54, and a lower segment 72B which extends into the semiconductor substrate 52. The upper segments 70A of the openings 70 and the upper segments 72A of the openings 72 have a first height H1 in a range from 5 μm to 20 μm, such as about 12 μm. The lower segments 70B of the openings 70 and the lower segments 72B of the openings 72 have a second height H2 in a range from 30 μm to 500 μm, such as about 130 μm. The height of the openings 70 may be substantially equal (within process variations) to the height of the openings 72.

During the dicing process, the upper segments 70A and 72A of the openings 70 and 72 may be formed by a dry etching performed with a first plasma, which comprises a fluorine plasma, a chlorine plasma, or the like. The first plasma may be generated from a gas source. The gas source includes a suitable etchant and a carrier gas. Acceptable fluorine-based etchants may include carbon tetrafluoride (CF₄), octafluorocyclobutane (C₄F₈), sulfur hexafluoride (SF₆), or the like. Acceptable chlorine-based etchants may include chlorine (Cl₂), carbon tetrachloride (CCl₄), or the like. The carrier gas may be an inert gas such as Ar, He, Xe, Ne, Kr, Rn, the like, or combinations thereof. The first plasma may be generated by a plasma generator such as an inductively coupled plasma system, a capacitively coupled plasma system, a remote plasma generator, or the like. The plasma generator generates radio frequency power that excites the gas source to a plasma state. The plasma generation power is pulsed between a low power (e.g., substantially zero watts) and a high power. The plasma generation power for the first plasma has a high power in a range from 0.5 kW to 1.5 kW, such as 1 kW.

The upper segments 70A of the openings 70 and the upper segments 72A of the openings 72 are formed during exposure to the first plasma. Upper portions of the second main sidewalls 71 and the chamfered sidewalls 73 are formed when the upper segments 70A of the openings 70 and the upper segments 72A of the openings 72 are formed. As a result, each upper portion of the second main sidewall 71 is in an opening 72, and comprises a corresponding sidewall of the dielectric layer 62 and a corresponding sidewall of the interconnect structure 54, which are coplanar with each other. Each chamfered sidewall 73 is in an opening 70, and comprises a corresponding sidewall of the dielectric layer 62 and a corresponding sidewall of the interconnect structure 54, which are coplanar with each other. The upper portions of the second main sidewalls 71 and the chamfered sidewalls 73 each have a constant slope in the cross-sectional views and are substantially smooth, continuous, and free of protrusions or cracks. The upper portions of the second main sidewalls 71 are substantially vertical and the chamfered sidewalls 73 are slightly slanted. A large acute angle α2 between the chamfered sidewalls 73 and top surfaces of the semiconductor substrate 52 is in a range between 85° and 90°. As discussed in greater detail below, the large acute angle α2 in such a range leads to a more complete and uniform coverage of the chamfered sidewalls 73 and an adjacent surface of a dielectric layer by a subsequently deposited gap-fill dielectric, thereby reducing the risk of delamination of the gap-fill dielectric. A right angle α3 between the upper portions of the second main sidewalls 71 and the top surfaces of the semiconductor substrate 52 is 90°.

Then the lower segments 70B and 72B of the openings 70 and 72 may be formed by a dry etching performed with a second plasma, which comprises a fluorine plasma, a chlorine plasma, or the like. The second plasma may be generated from a gas source, similar to the first plasma. In some embodiments, the second plasma is generated from the same gas source as the first plasma. The plasma generation power for the second plasma has a high power in a range from 2.7 kW to 3.3 kW, such as about 3 kW. The high power of the second plasma is larger than the high power of the first plasma. Lower portions of the second main sidewalls 71 and substrate sidewalls 73′ are formed when the lower segments 70B of the openings 70 and the lower segments 72B of the openings 72 are formed. As a result, each lower portion of the second main sidewall 71 is in an opening 72, and comprises a corresponding sidewall of the semiconductor substrate 52, which is coplanar with the corresponding upper portion of the second main sidewall 71. Each substrate sidewall 73′ is in an opening 70, and comprises a corresponding sidewall of the semiconductor substrate 52, which abuts (or adjoins) the corresponding chamfered sidewall 73. The lower portions of the second main sidewalls 71 and the substrate sidewalls 73′ each have a constant slope in the cross-sectional views and are substantially smooth, continuous, and free of protrusions or cracks. Since the high power of the second plasma is larger than the high power of the first plasma, the second plasma has a higher density of ions than the first plasma, which leads to a more anisotropic dry etching by the second plasma than by the first plasma. In other words, a degree of anisotropy of the second dry etching is larger than a degree of anisotropy of the first dry etching. As a result, the lower portions of the second main sidewalls 71 and substrate sidewalls 73′ are substantially vertical. A right angle β2 between the substrate sidewalls 73′ and the top surfaces of the semiconductor substrate 52 is 90°. The right angle β2 is larger than the acute angle α2. As a result, an obtuse angle between each chamfered sidewall 73 and the corresponding substrate sidewall 73′ is in a range between 175° and 180°. A right angle β3 between the lower portions of the second main sidewalls 71 and the top surfaces of the semiconductor substrate 52 is 90°. The configuration of the first main sidewalls 69 are substantially the same as the second main sidewalls 71. After the dicing process, the mask 66 is removed using an acceptable ashing or stripping process.

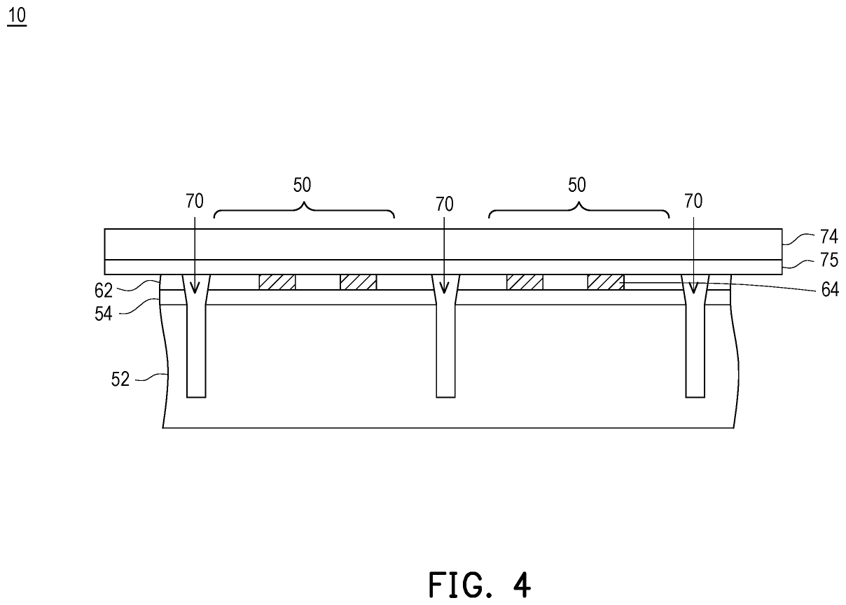

In FIG. 4, the wafer 10 is attached to a carrier 74 by an adhesive 75, which may be on the dielectric layer 62 and the die connectors 64. The carrier 74 may be a semiconductor carrier, a glass carrier, a ceramic carrier, or the like. The carrier 74 may be a wafer. In some embodiments, the adhesive 75 is a thermal-release layer, such as an epoxy-based light-to-heat-conversion (LTHC) release material, which loses its adhesive property when heated. In some embodiments, the adhesive 75 is a UV glue, which loses its adhesive property when exposed to UV light; or the like.

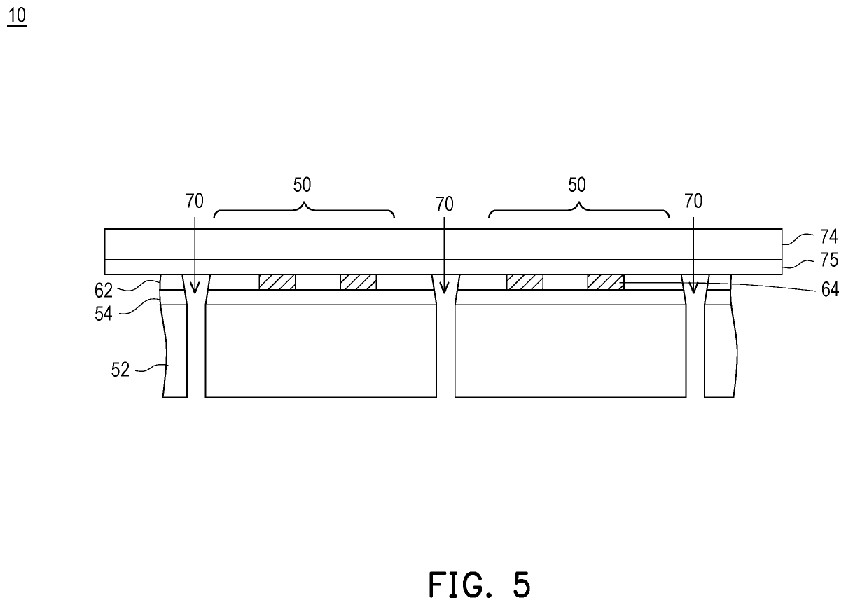

In FIG. 5, a thinning process is performed on the semiconductor substrate 52, which results in the singulation of the integrated circuit die 50 from each other. The thinning process may be performed using a chemical-mechanical polish (CMP), a grinding process, an etch-back process, the like, or a combination thereof, whereby chemical etchants and abrasives may be utilized to react and grind away portions of the semiconductor substrate 52 until the openings 70 and 72 are exposed and each integrated circuit die 50 is singulated from the other integrated circuit dies 50. A cleaning process or rinsing process may be performed after the thinning process.

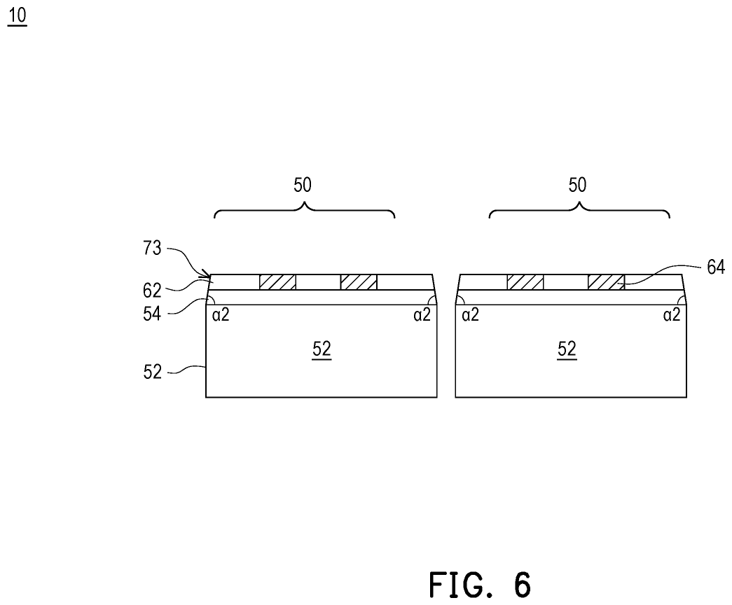

In FIG. 6, the singulated integrated circuit dies 50 are detached from the carrier 74 (shown in FIG. 5). The detaching process may include projecting a light beam such as a laser beam or a UV light beam on the adhesive 75 (shown in FIG. 5) so that the adhesive 75 decomposes upon exposure to the light beam and the carrier 74 can be removed.

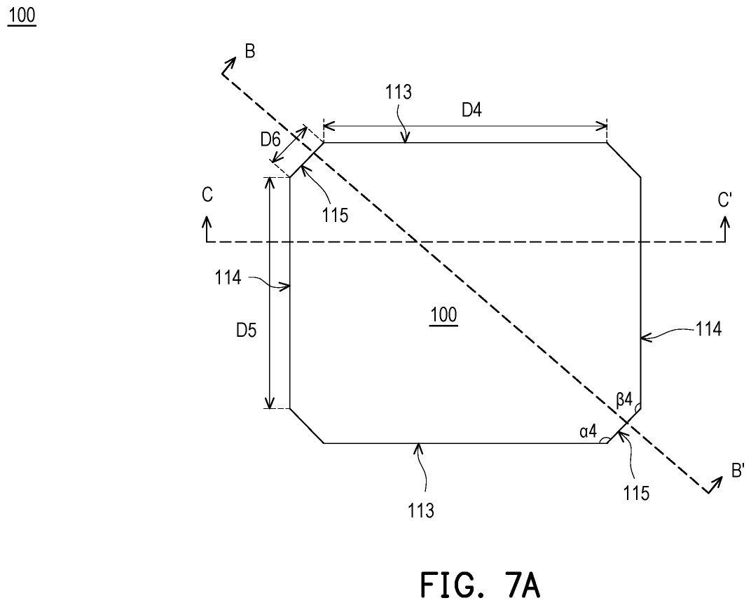

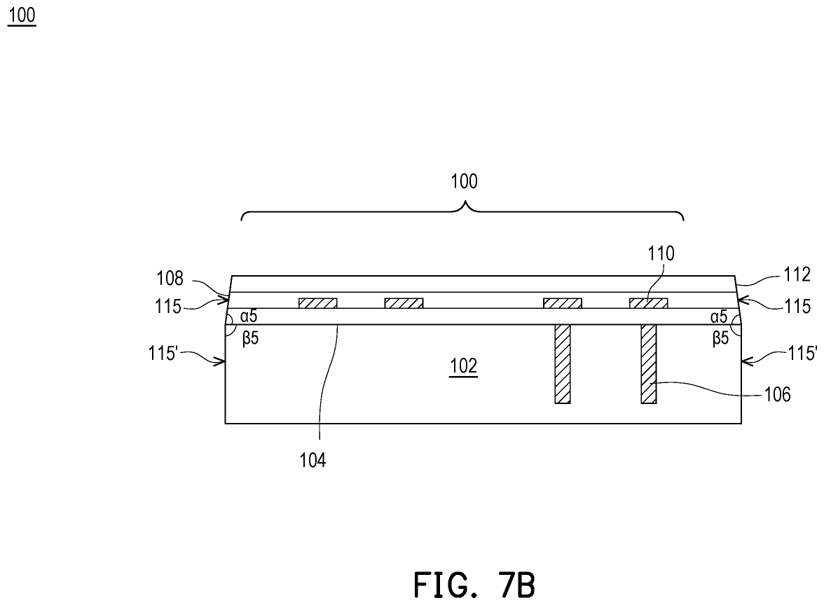

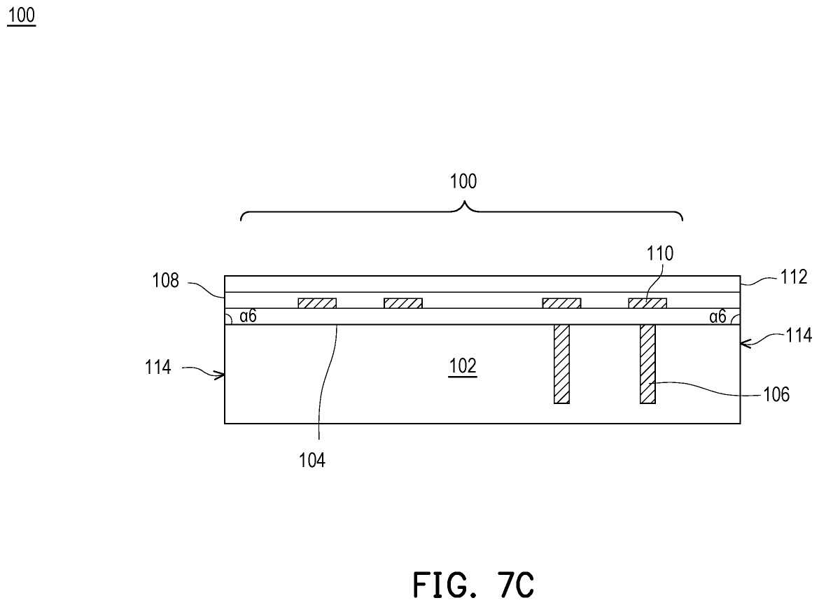

FIGS. 7A through 7C are views of an integrated circuit die 100, in accordance with some embodiments. FIG. 7A is a top-down view. FIG. 7B is a cross-sectional view shown along respective reference cross-sections B-B′ in the top-down view. FIG. 7C is a cross-sectional view shown along respective reference cross-sections C-C′ in the top-down view.

The integrated circuit die 100 may be a logic die (e.g., CPU, GPU, SoC, AP, microcontroller, etc.), a memory die (e.g., DRAM die, SRAM die, etc.), a power management die (e.g., PMIC die), a RF die, a sensor die, a MEMS die, a signal processing die (e.g., DSP die), a front-end die (e.g., AFE dies), the like, or combinations thereof. The materials and manufacturing processes of the features in the integrated circuit dies 100 may be found by referring to the like features in the integrated circuit dies 50. The integrated circuit die 100 includes a semiconductor substrate 102, which has an active surface (e.g., the surface facing upwards in FIG. 7B), sometimes called a front side, and an inactive surface (e.g., the surface facing downwards in FIG. 7B), sometimes called a back side. Devices (not separately illustrated) are disposed at the active surface of the semiconductor substrate 102. The devices may be active devices (e.g., transistors, diodes, etc.), capacitors, resistors, etc. An interconnect structure 104 is disposed over the active surface of the semiconductor substrate 102. A dielectric layer 108 is over the interconnect structure 104, at the front side of the integrated circuit die 100. Optionally, one or more passivation layer(s) (not separately illustrated) are disposed between the dielectric layer 108 and the interconnect structure 104. Die connectors 110 are disposed on the interconnect structure 104 and in the dielectric layer 108. The dielectric layer 108 may extend over the die connectors 110. A bonding layer 112 is disposed on the dielectric layer 108. The bonding layer 112 may comprise a dielectric material, such as silicon dioxide or the like, and may be formed by a suitable deposition process such as CVD, atomic layer deposition (ALD), or the like. The bonding layer 112 may be used for bonding to a carrier in a subsequent process.

The integrated circuit die 100 further includes conductive vias 106 extending into the semiconductor substrate 102. The conductive vias 106 are electrically coupled to the metallization patterns of the interconnect structure 104. The semiconductor substrate 102 may be thinned in a subsequent process to expose the conductive vias 106 at the inactive surface of the semiconductor substrate 102. After the exposure process, the conductive vias 106 are through-substrate vias, such as through-silicon vias (TSV). In the illustrated embodiment, the conductive vias 106 are formed by a via-first process, such that the conductive vias 106 extend into the semiconductor substrate 102 but not the interconnect structure 104. The conductive vias 106 formed by a via-first process are connected to a lower metallization pattern of the interconnect structure 104. In another embodiment, the conductive vias 106 are formed by a via-middle process, such that the conductive vias 106 extend through a portion of the interconnect structure 104 and into the semiconductor substrate 102. The conductive vias 106 formed by a via-middle process are connected to a middle metallization pattern of the interconnect structure 104. In yet another embodiment, the conductive vias 106 are formed by a via-last process, such that the conductive vias 106 extend through an entirety of the interconnect structure 104 and into the semiconductor substrate 102. The conductive vias 106 formed by a via-last process are connected to an upper metallization pattern of the interconnect structure 104.

Similar to the integrated circuit dies 50, the integrated circuit dies 100 are also formed as a part of a wafer and subsequently singulated to form discrete integrated circuit dies 100. The singulation process (e.g. plasma dicing) may be substantially the same or similar to the singulation process that form the integrated circuit dies 50. The shape of the integrated circuit die 100 in the top-down view may be an octagon, which may help to reduce the stress in the corners of the integrated circuit die 100, thereby reducing the risk of cracking in the corners of the integrated circuit die 100. FIG. 7A illustrates the shape of the integrated circuit die 100 as an octagon as an example, other shapes are contemplated. The integrated circuit die 100 comprises first main sidewalls 113, which extend in the first direction (e.g., horizontal), second main sidewalls 114, which extend in the second direction (e.g., vertical), and chamfered sidewalls 115, which connect each first main sidewall 113 to a neighboring second main sidewall 114. As a result, each chamfered sidewall 115 abuts (or adjoins) a first main sidewall 113 on one side and a second main sidewall 114 on another side, such that the chamfered sidewall 115 extends between the first main sidewall 113 and the second main sidewall 114. An obtuse angle α4 between a first main sidewall 113 and a neighboring chamfered sidewall 115 is in a range from 130° to 140°. An obtuse angle β1 between a second main sidewall 114 and a neighboring chamfered sidewall 115 is in a range from 130° to 140°. Each first main sidewall 113 may have a length D4 in a range from 1 μm to 30 mm in the top-down view. Each second main sidewall 114 may have a length D5 in a range from 1 μm to 30 mm in the top-down view. Each chamfered sidewall 115 may have a length D6 in a range from 1 μm to 300 μm in the top-down view. The length D4 and the length D5 may be equal. The length D4 and the length D5 may be larger than the length D6.

Each second main sidewall 114 comprises a corresponding sidewall of the bonding layer 112, a corresponding sidewall of the dielectric layer 108, a corresponding sidewall of the interconnect structure 104, and a corresponding sidewall of the semiconductor substrate 102, which are coplanar with each other. Each chamfered sidewall 115 comprises a corresponding sidewall of the bonding layer 112, a corresponding sidewall of the dielectric layer 108, and a corresponding sidewall of the interconnect structure 104, which are coplanar with each other. The semiconductor substrate 102 comprises substrate sidewalls 115′ and each substrate sidewall 115′ abuts (or adjoins) a corresponding chamfered sidewall 115. The second main sidewalls 114, the chamfered sidewalls 115, and the substrate sidewall 115′ may each have a constant slope in the cross-sectional views and may be substantially smooth, continuous, and free of protrusions or cracks. The second main sidewalls 114 and the substrate sidewall 115′ are substantially vertical and the chamfered sidewalls 115 are slightly slanted. A large acute angle α5 between the chamfered sidewalls 115 and a top surface of the semiconductor substrate 102 is in a range between 85° and 90°. As discussed in greater detail below, the large acute angle α5 in such a range leads to a more complete and uniform coverage of the chamfered sidewalls 115 and an adjacent surface of a bonding layer by a subsequently deposited gap-fill dielectric, thereby reducing the risk of delamination of the gap-fill dielectric. A right angle β5 between the substrate sidewalls 115′ and the top surface of the semiconductor substrate 102 is 90°. The right angle β5 is larger than the acute angle α5. As a result, an obtuse angle between each chamfered sidewall 115 and the corresponding substrate sidewall 115′ is in a range between 175° and 180°. A right angle α6 between second main sidewalls 114 and the top surface of the semiconductor substrate 102 is 90°. The configuration of the first main sidewalls 113 are substantially the same as the second main sidewalls 114.

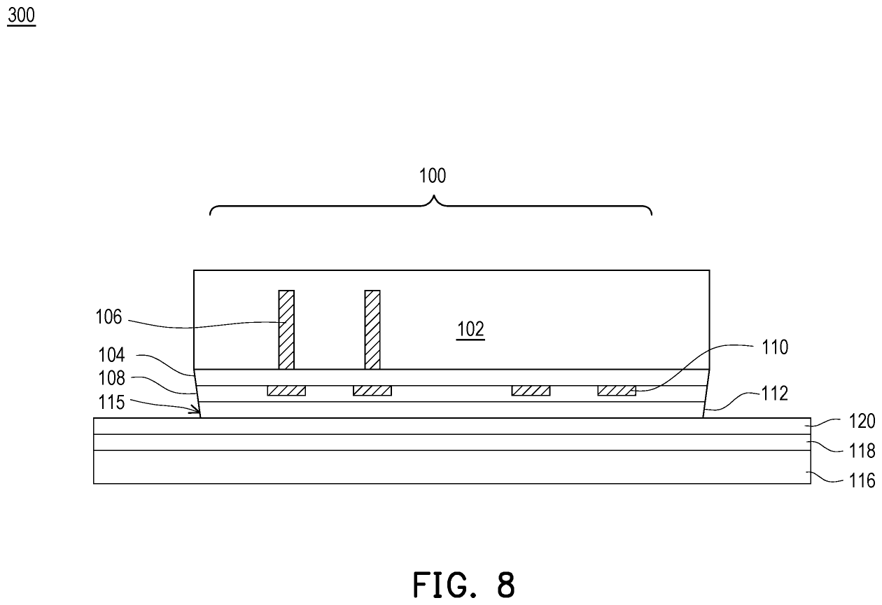

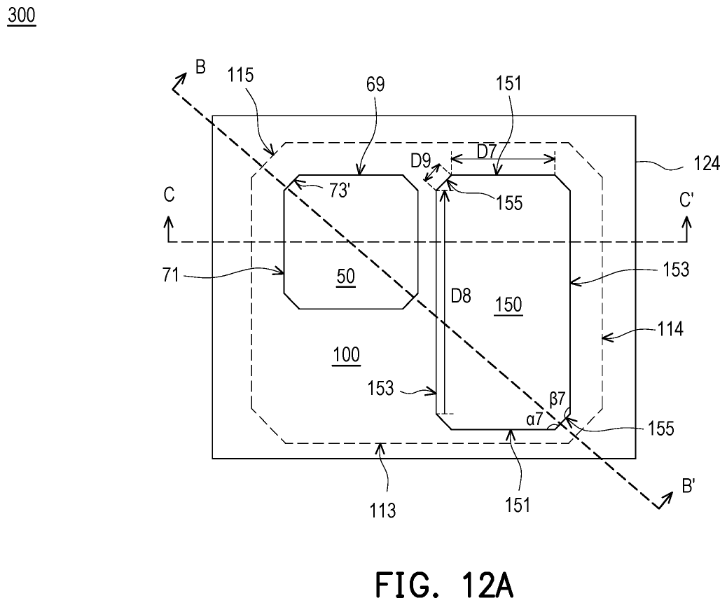

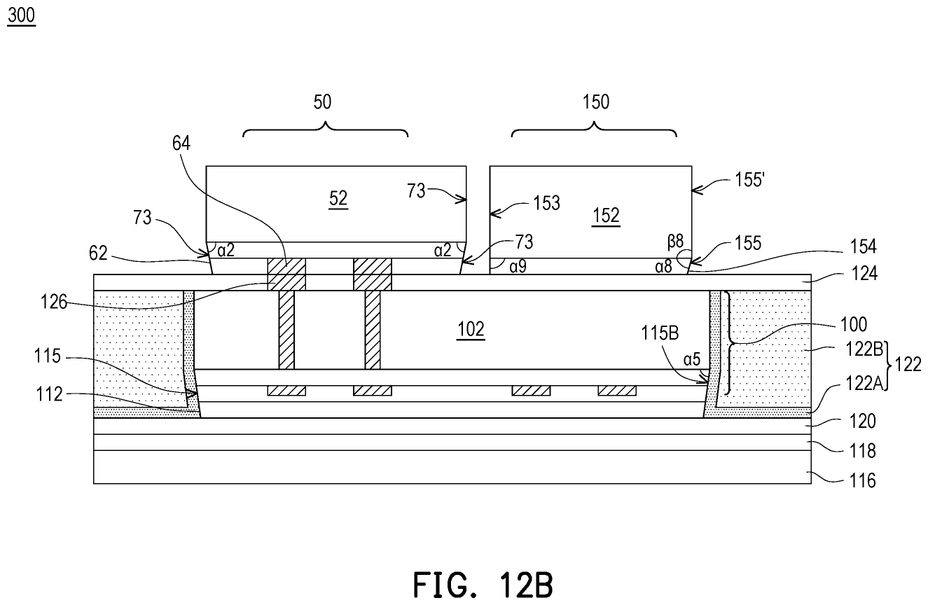

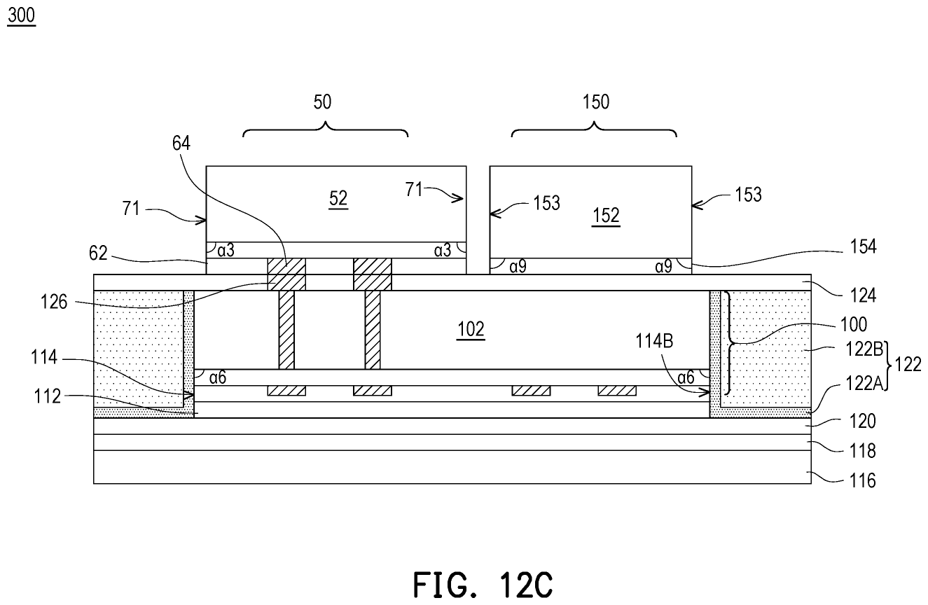

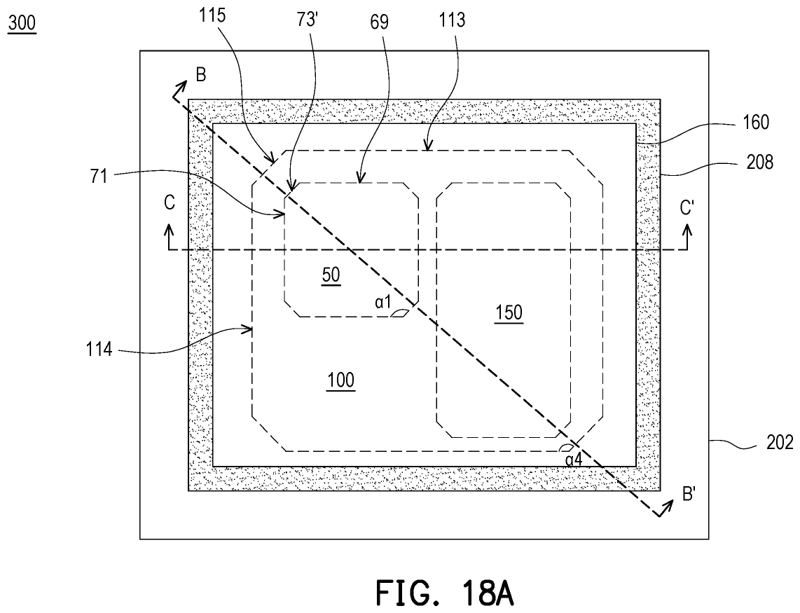

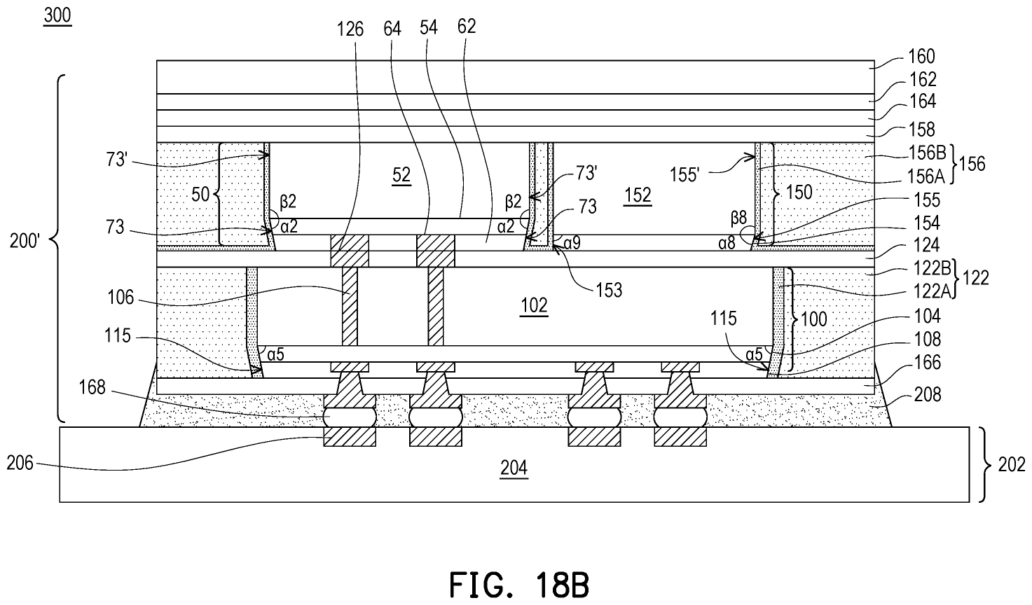

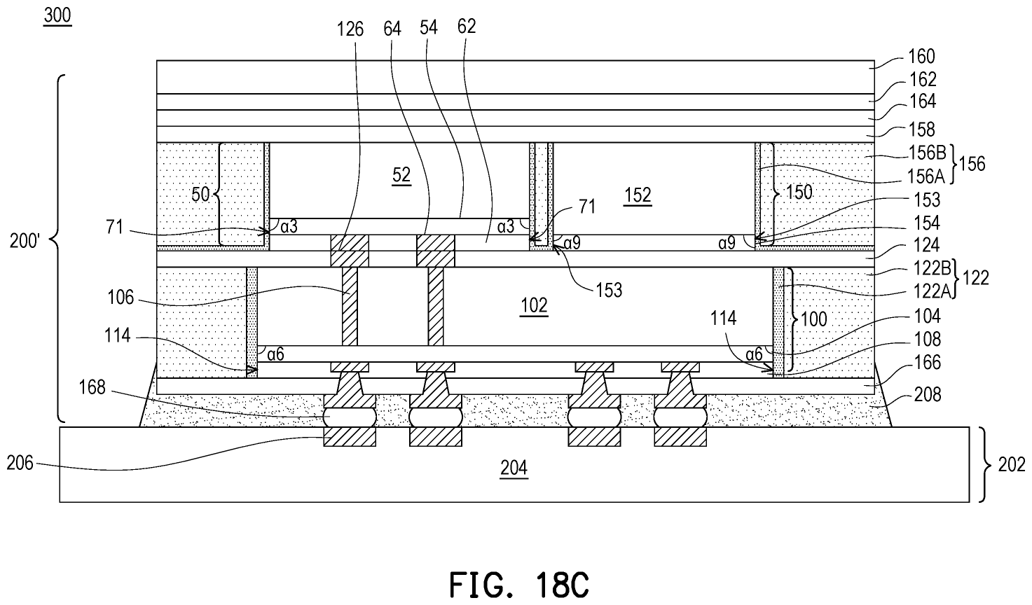

FIGS. 8 through 18C are views of intermediate stages in the manufacturing of an integrated circuit package 300, in accordance with some embodiments. FIGS. 12A and 18A are top-down views. FIGS. 8, 9, 10, 11, 12B, 13, 14, 15, 16, 17, and 18B are cross-sectional views shown along respective reference cross-sections B-B′ in the top-down views. FIGS. 12C and 18C are cross-sectional views shown along respective reference cross-sections C-C′ in the top-down views.

In FIG. 8, an integrated circuit die 100 is bonded to a carrier 116. The carrier 116 may be a semiconductor carrier, a glass carrier, a ceramic carrier, or the like. The carrier 116 may be a wafer. FIG. 8 illustrates one integrated circuit die 100 bonded to the carrier 116 as an example, two or more integrated circuit dies 100 may be bonded to the carrier 116 and processed together during the subsequent manufacturing steps until singulated into individual package components. One or more bonding layers may be disposed on the carrier 116. In some embodiments, a first bonding layer 118 is disposed on the carrier 116. The first bonding layer 118 may comprise a dielectric material, such as silicon dioxide or the like. A second bonding layer 120 is disposed on the first bonding layer 118. The second bonding layer 120 may comprise a dielectric material, such as silicon oxynitride or the like.

The integrated circuit die 100 may be bonded to the second bonding layer 120 by placing the integrated circuit die 100 on the second bonding layer 120 by a pick-and-place process or the like, then bonding the integrated circuit die 100 to the second bonding layer 120. As an example of the bonding process, the integrated circuit die 100 may be bonded to the second bonding layer 120 by dielectric-to-dielectric bonding without using any adhesive material (e.g., die attach film). The bonding may include a pre-bonding and an annealing. During the pre-bonding, a small pressing force is applied to press the integrated circuit die 100 against the second bonding layer 120. The pre-bonding is performed at a low temperature, such as room temperature, and after the pre-bonding, the bonding layer 112 is bonded to the second bonding layer 120. The bonding strength is then improved in a subsequent annealing step, in which the bonding layer 112 and the second bonding layer 120 are annealed. After the annealing, direct bonds such as fusion bonds are formed, bonding the bonding layer 112 to the second bonding layer 120. The bonds may be covalent bonds between the material of the bonding layer 112 and the second bonding layer 120.

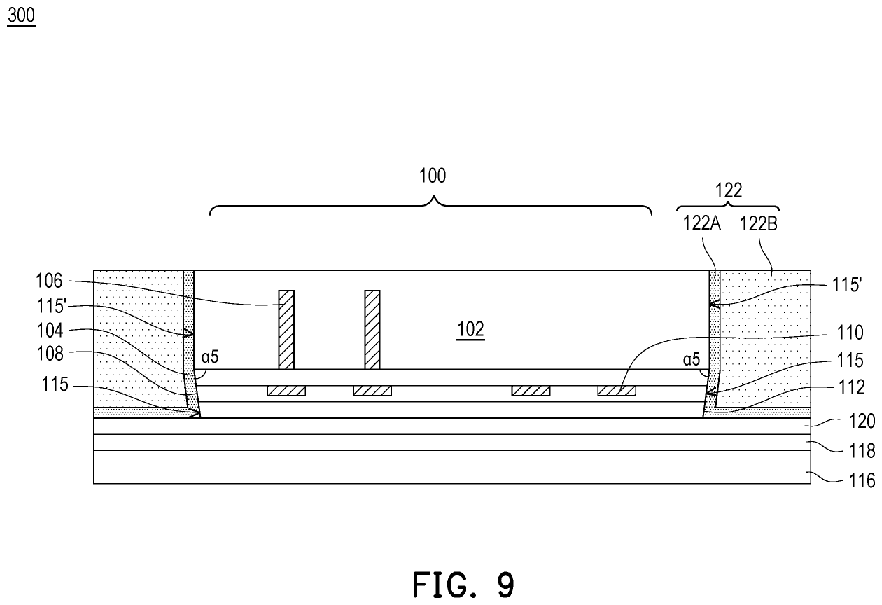

In FIG. 9, a gap-fill dielectric 122 is formed around the integrated circuit die 100 and between the neighboring integrated circuit dies 100 over the carrier 116. The gap-fill dielectric 122 may be formed of one or more dielectric materials. Acceptable gap-fill dielectric materials include oxides such as silicon oxide, PSG, BSG, BPSG, a TEOS based oxide, or the like; nitrides such as silicon nitride, silicon oxynitride, or the like; combinations thereof; or the like, which may be formed by a suitable deposition process such as CVD, ALD, or the like. Initially, the gap-fill dielectric 122 may bury or cover the back side of the integrated circuit die 100. A removal process may be performed to level surfaces of the gap-fill dielectric 122 with the back side surface of integrated circuit die 100. In some embodiments, a thinning process such as a CMP, a grinding process, an etch-back process, combinations thereof, or the like, is utilized.

In some embodiments, the gap-fill dielectric 122 is multi-layered, including a liner layer and a main layer. In the illustrated embodiment, the gap-fill dielectric 122 includes a liner 122A and a main filler 122B, where the liner 122A is formed of a nitride (previously described), and where the main filler 122B is formed of an oxide (previously described). The liner 122A may conform to the chamfered sidewalls 115 and the substrate sidewalls 115′ of the integrated circuit die 100, and to the exposed top surface of the second bonding layer 120. The main filler 122B is over the liner 122A, such that the liner 122A is disposed between the main filler 122B and the integrated circuit die 100 as well as the exposed portions of the second bonding layer 120.

Due to the large acute angle α5 between the chamfered sidewalls 115 and the top surface of the semiconductor substrate 102 (shown as a top surface in FIG. 3A and a bottom surface in FIG. 9), which is in a range between 85° and 90°, chemicals used for the deposition of the gap-fill dielectric 122 have better access to the space between the chamfered sidewalls 115 and the adjacent top surface of the second bonding layer 120, thereby leading to a more complete and uniform coverage of the chamfered sidewalls 115 and the adjacent top surface of the second bonding layer 120 by the deposited gap-fill dielectric 122. As a result, the risk of delamination of the gap-fill dielectric 122 is reduced during the manufacturing and operation of the integrated circuit package 300, thereby improving the reliability of the integrated circuit package 300.

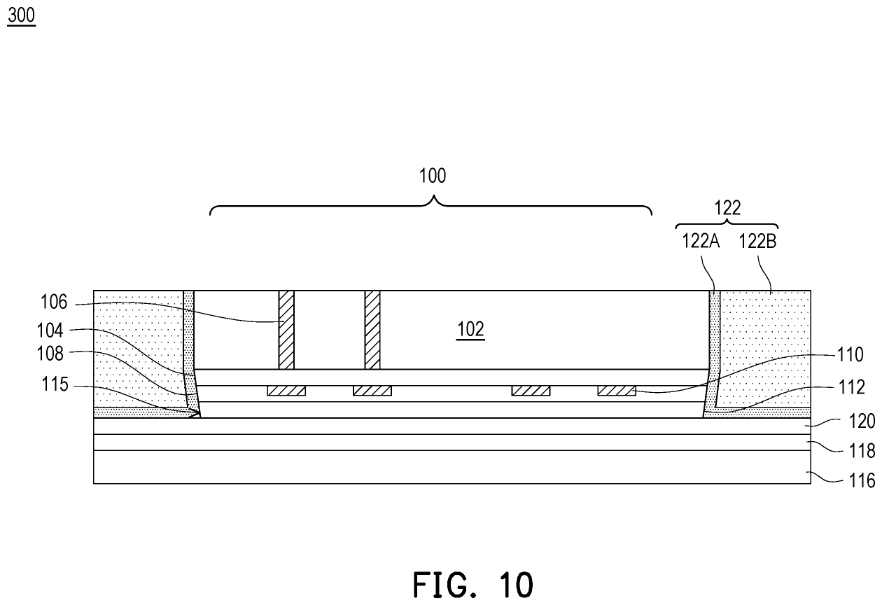

In FIG. 10, the semiconductor substrate 102 are thinned to expose the conductive vias 106. Portions of the gap-fill dielectric 122 may also be removed by the thinning process. The thinning process may be, a CMP, a grinding process, an etch-back process, combinations thereof, or the like, which is performed at the back sides of the integrated circuit die 100. After the thinning process, surfaces of the gap-fill dielectric 122 and the integrated circuit die 100 (including the semiconductor substrate 102 and the conductive vias 106) are substantially coplanar (within process variations).

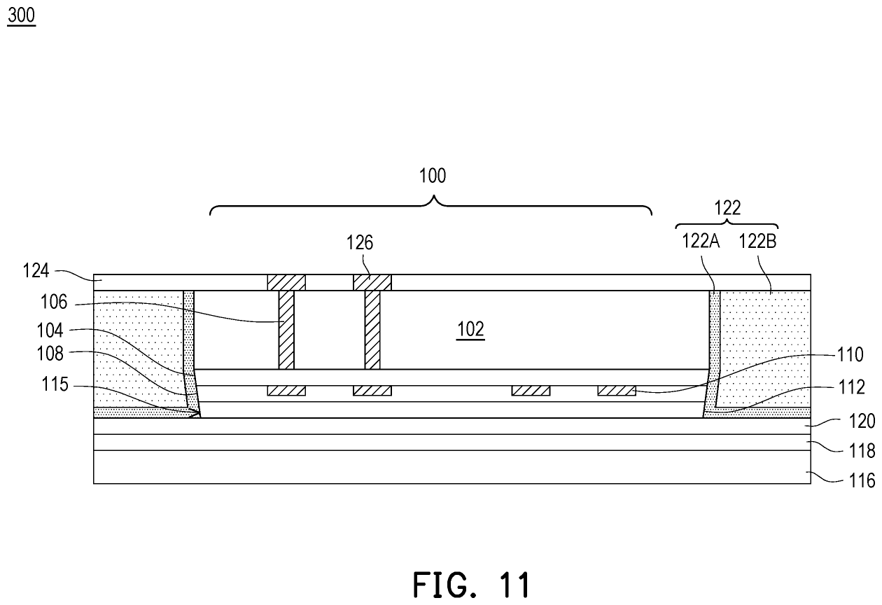

In FIG. 11, a dielectric layer 124 is formed on the gap-fill dielectric 122 and the back side of the integrated circuit die 100, and die connectors 126 are formed in the dielectric layer 124. The die connectors 126 may extend through the dielectric layer 124 and connect to the conductive vias 106. The dielectric layer 124 may electrically isolate the conductive vias 106 from one another, thus avoiding shorting, and may also be utilized in a subsequent bonding process. The dielectric layer 124 may be formed of an oxide such as silicon oxide, PSG, BSG, BPSG, a TEOS based oxide, or the like, which may be formed by a suitable deposition process such as CVD, or the like. Other suitable dielectric materials, such as a low temperature polyimide material, polybenzoxazole PBO, an encapsulant, combinations thereof, or the like, may also be utilized. The die connectors 126 may be formed by a damascene process, such as a single damascene process, a dual damascene process, or the like. The die connectors 126 may be formed of a metal, such as copper, aluminum, or the like, which can be formed by plating, or the like. In some embodiments, a planarization process such as a CMP, a grinding process, an etch-back process, combinations thereof, or the like, is performed on the dielectric layer 124 and the die connectors 126. After the planarization process, surfaces of the dielectric layer 124 and the die connectors 126 may be substantially coplanar (within process variations).

In FIGS. 12A through 12C, the integrated circuit die 50 is bonded to the dielectric layer 124 and the die connectors 126, and an inactive die 150 is bonded to the dielectric layer 124. The die connectors 126 electrically couple the integrated circuit die 50 and the integrated circuit die 100. The inactive die 150 comprises a semiconductor substrate 152 and a dielectric layer 154. The materials and manufacturing processes of the features in the inactive die 150 may be found by referring to the like features in the integrated circuit dies 50. The layout of the integrated circuit die 50 and the inactive die 150 on the integrated circuit die 100 shown in FIG. 12A is an example, other layouts with more integrated circuit dies 50 and no or more inactive dies 150 are contemplated.

Similar to the integrated circuit dies 50, the inactive die 150 is also formed as a part of a wafer and subsequently singulated to form discrete inactive dies 150. The singulation process (e.g. plasma dicing) may be substantially the same or similar to the singulation process that form the integrated circuit dies 50. The shape of inactive die 150 in the top-down view may be an octagon, which may help to reduce the stress in the corners of the inactive die 150, thereby reducing the risk of cracking in the corners of the inactive die 150. FIG. 12A illustrates the shape of the inactive die 150 as an octagon as an example, other shapes are contemplated. The inactive die 150 comprises first main sidewalls 151, which extend in the first direction (e.g., horizontal) in the top-down view, second main sidewalls 153, which extend in the second direction (e.g., vertical) in the top-down view, and chamfered sidewalls 155, which connect each first main sidewall 151 to a neighboring second main sidewall 153. As a result, each chamfered sidewall 155 abuts (or adjoins) a first main sidewall 151 on one side and a second main sidewall 153 on another side, such that the chamfered sidewall 155 extends between the first main sidewall 151 and the second main sidewall 153. An obtuse angle α7 between a first main sidewall 151 and a neighboring chamfered sidewall 155 is in a range from 130° to 140°. An obtuse angle β7 between a second main sidewall 153 and a neighboring chamfered sidewall 155 is in a range from 130° to 140°. Each first main sidewall 151 may have a length D7 in a range from 1 μm to 30 mm in the top-down view. Each second main sidewall 153 may have a length D8 in a range from 1 μm to 30 mm in the top-down view. Each chamfered sidewall 155 may have a length D9 in a range from 1 μm to 300 μm in the top-down view. The length D7 and the length D8 may be equal. The length D7 and the length D8 may be larger than the length D9.

Each second main sidewall 153 comprises a corresponding sidewall of the dielectric layer 154 and a corresponding sidewall of the semiconductor substrate 152, which are coplanar with each other. Each chamfered sidewall 155 comprises a corresponding sidewall of dielectric layer 154. The semiconductor substrate 152 comprises substrate sidewalls 155′ and each substrate sidewall 155′ abuts (or adjoins) a corresponding chamfered sidewall 155. The second main sidewalls 153, the chamfered sidewalls 155, and the substrate sidewall 155′ may each have a constant slope in the cross-sectional views and may be substantially smooth, continuous, and free of protrusions or cracks. The second main sidewalls 153 and the substrate sidewall 155′ are substantially vertical and the chamfered sidewalls 155 are slightly slanted. A large acute angle α8 between the chamfered sidewalls 115 and a bottom surface of the semiconductor substrate 152 is in a range between 85° and 90°. As discussed in greater detail below, the large acute angle α8 in such a range leads to a more complete and uniform coverage of the chamfered sidewalls 155 and an adjacent surface of a dielectric layer by a subsequently deposited gap-fill dielectric, thereby reducing the risk of delamination of the gap-fill dielectric. A right angle β8 between the substrate sidewalls 155′ and the bottom surface of the semiconductor substrate 102 is 90°. The right angle β8 is larger than the acute angle α8. As a result, an obtuse angle between each chamfered sidewall 155 and the corresponding substrate sidewall 155′ is in a range between 175° and 180°. A right angle α9 between second main sidewalls 153 and the bottom surface of the semiconductor substrate 152 is 90°. The configuration of the first main sidewalls 151 are substantially the same as the second main sidewalls 153.

The integrated circuit die 50 may be bonded to the dielectric layer 124 and the die connectors 126 by placing the integrated circuit die 50 on the dielectric layer 124 and the die connectors 126 by a pick-and-place process or the like, then bonding the integrated circuit die 50 to the dielectric layer 124 and the die connectors 126. The inactive die 150 may be bonded to the dielectric layer 124 by placing inactive die 150 on the dielectric layer 124 by a pick-and-place process or the like, then bonding the inactive die 150 to the dielectric layer 124.

The integrated circuit die 50 may be bonded to the dielectric layer 124 and the die connectors 126 by hybrid bonding. The dielectric layers 62 of the integrated circuit die 50 is directly bonded to the dielectric layer 124 through dielectric-to-dielectric bonding, without using any adhesive material (e.g., die attach film). The die connectors 64 of the integrated circuit die 50 are directly bonded to respective die connectors 126 through metal-to-metal bonding, without using any eutectic material (e.g., solder). The bonding may include a pre-bonding and an annealing. During the pre-bonding, a small pressing force is applied to press the integrated circuit die 50 against the dielectric layer 124 and the die connectors 126. The pre-bonding is performed at a low temperature, such as room temperature, and after the pre-bonding, the dielectric layer 62 is bonded to the dielectric layer 124. The bonding strength is then improved in a subsequent annealing step, in which the dielectric layer 124, the die connectors 126, the dielectric layer 62, and the die connectors 64 are annealed. After the annealing, direct bonds such as fusion bonds are formed, bonding the dielectric layer 124 to the dielectric layer 62. The bonds may be covalent bonds between the material of the dielectric layer 124 and the material of the dielectric layer 62. The die connectors 126 are connected to the die connectors 64 with a one-to-one correspondence. The die connectors 126 and the die connectors 64 may be in physical contact after the pre-bonding, or may expand to be brought into physical contact during the annealing. Further, during the annealing, the material of the die connectors 126 and the die connectors 64 intermingle, so that metal-to-metal bonds are also formed. Hence, the resulting bonds between the integrated circuit die 50, and the dielectric layer 124 as well as the die connectors 126 are hybrid bonds that include both dielectric-to-dielectric bonds and metal-to-metal bonds.

The inactive die 150 may be bonded to the dielectric layer 124 by dielectric-to-dielectric bonding without using any adhesive material (e.g., die attach film). The bonding may include a pre-bonding and an annealing. During the pre-bonding, a small pressing force is applied to press the inactive die 150 against the dielectric layer 124. The pre-bonding is performed at a low temperature, such as room temperature, and after the pre-bonding, the dielectric layer 154 is bonded to the dielectric layer 124. The bonding strength is then improved in a subsequent annealing step, in which the dielectric layer 154 and the dielectric layer 124 are annealed. After the annealing, direct bonds such as fusion bonds are formed, bonding the dielectric layer 154 to the dielectric layer 124. The bonds may be covalent bonds between the material of the dielectric layer 154 and the dielectric layer 124.

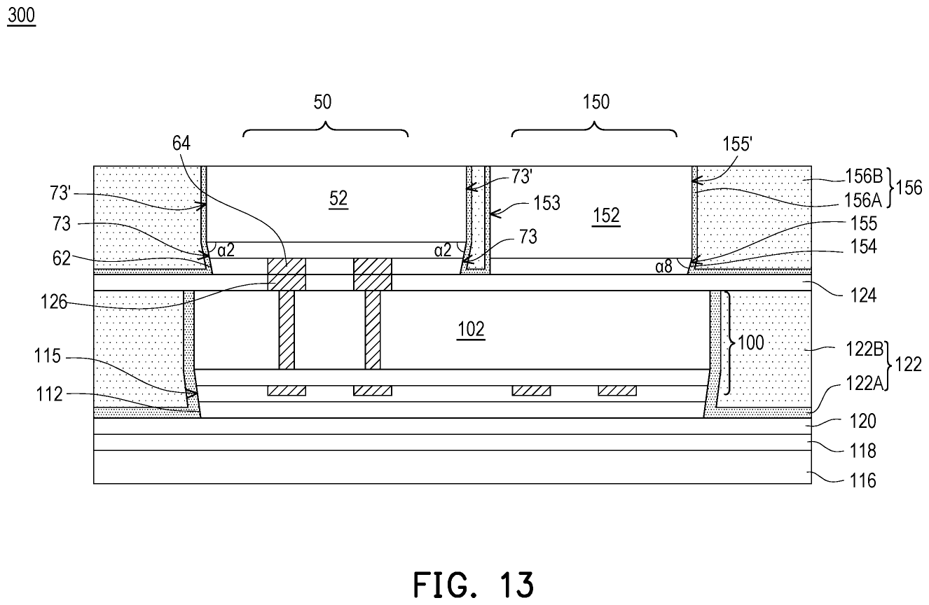

In FIG. 13, a gap-fill dielectric 156 is formed around the integrated circuit die 50, around the inactive die 150, and between the neighboring integrated circuit dies 50 and the inactive dies 150 over the dielectric layer 124. The gap-fill dielectric 156 may be formed of one or more dielectric materials. Acceptable gap-fill dielectric materials include oxides such as silicon oxide, PSG, BSG, BPSG, a TEOS based oxide, or the like; nitrides such as silicon nitride, silicon oxynitride, or the like; combinations thereof; or the like, which may be formed by a suitable deposition process such as CVD, ALD, or the like. In some embodiments, the gap-fill dielectric 156 is formed of the same dielectric material(s) as the gap-fill dielectric 122. The gap-fill dielectric 156 may be formed by a same or similar method(s) as the gap-fill dielectric 122.

In some embodiments, the gap-fill dielectric 156 is multi-layered, including a liner layer and a main layer. In the illustrated embodiment, the gap-fill dielectric 156 includes a liner 156A and a main filler 156B, where the liner 156A is formed of a nitride (previously described), and where the main filler 156B is formed of an oxide (previously described). The liner 156A may conform to the sidewalls of the integrated circuit die 50 (e.g., the chamfered sidewalls 73 and substrate sidewalls 73′), the sidewalls of the inactive die 150 (the second main sidewalls 153, the chamfered sidewalls 155, and the substrate sidewalls 155′), and the exposed top surface of the dielectric layer 124. The main filler 156B is over the liner 156A, such that the liner 156A is disposed between the main filler 156B and the integrated circuit die 50, the inactive die 150, as well as the exposed portions of the dielectric layer 124.

Due to the large acute angle α2 between the chamfered sidewalls 73 and the top surface of the semiconductor substrate 52 (shown as a top surface in FIG. 7B and a bottom surface in FIG. 13) of the integrated circuit die 50, which is in a range between 85° and 90°, chemicals used for the deposition of the gap-fill dielectric 156 have better access to the space between the chamfered sidewalls 73 and the adjacent top surface of the dielectric layer 124, thereby leading to a more complete and uniform coverage of the chamfered sidewalls 73 and the adjacent surface of the dielectric layer 124 by the deposited gap-fill dielectric 156. For similar reasons, the large acute angle α8 between the chamfered sidewalls 155 and the bottom surface of the semiconductor substrate 152 of the inactive die 150, which is in a range between 85° and 90°, also leads to a more complete and uniform coverage of the chamfered sidewalls 155 and the adjacent surface of the dielectric layer 124 by the deposited gap-fill dielectric 156. As a result, the risk of delamination of the gap-fill dielectric 156 is reduced during the manufacturing and operation of the integrated circuit package 300, thereby improving the reliability of the integrated circuit package 300.

A thinning process may be performed to remove portions of the semiconductor substrate 52, the semiconductor substrate 152, and the gap-fill dielectric 156. The thinning process may be, a CMP, a grinding process, an etch-back process, combinations thereof, or the like, which is performed at the back sides of the integrated circuit die 50. After the thinning process, surfaces of the gap-fill dielectric 156, the integrated circuit die 50 (including the semiconductor substrate 102), the inactive die 150 (including the semiconductor substrate 152) are substantially coplanar (within process variations).

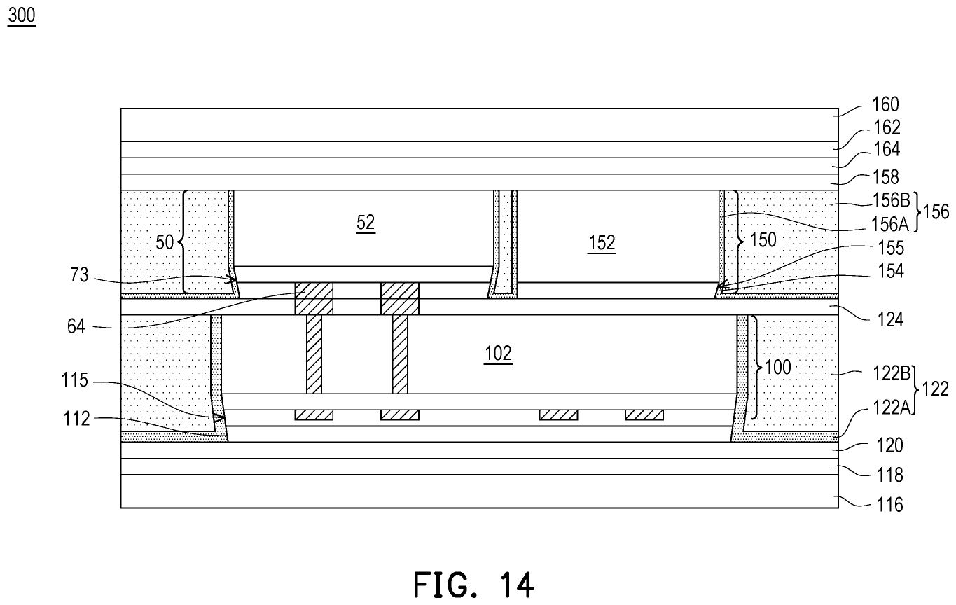

In FIG. 14, a bonding layer 158 is formed on the semiconductor substrate 102, the semiconductor substrate 152, and the gap-fill dielectric 156, and the structure over the carrier 116 is bonded to a carrier 160. The bonding layer 158 may comprise a dielectric material, such as silicon dioxide or the like, and may be formed by a suitable deposition process such as CVD, ALD, or the like. The carrier 160 may be a semiconductor carrier, a glass carrier, a ceramic carrier, or the like. The carrier 160 may be a wafer having a same or similar size as the carrier 116. One or more bonding layers may be disposed on the carrier 160. In some embodiments, a first bonding layer 162 is disposed on the carrier 160. The first bonding layer 162 may comprise a dielectric material, such as silicon dioxide or the like. A second bonding layer 164 is disposed on the first bonding layer 162. The second bonding layer 164 may comprise a dielectric material, such as silicon oxynitride or the like. The structure over the carrier 116 is bonded to the carrier 160 by bonding the bonding layer 158 and the second bonding layer 164 by a same or similar process as used for bonding the bonding layer 112 and the second bonding layer 120.

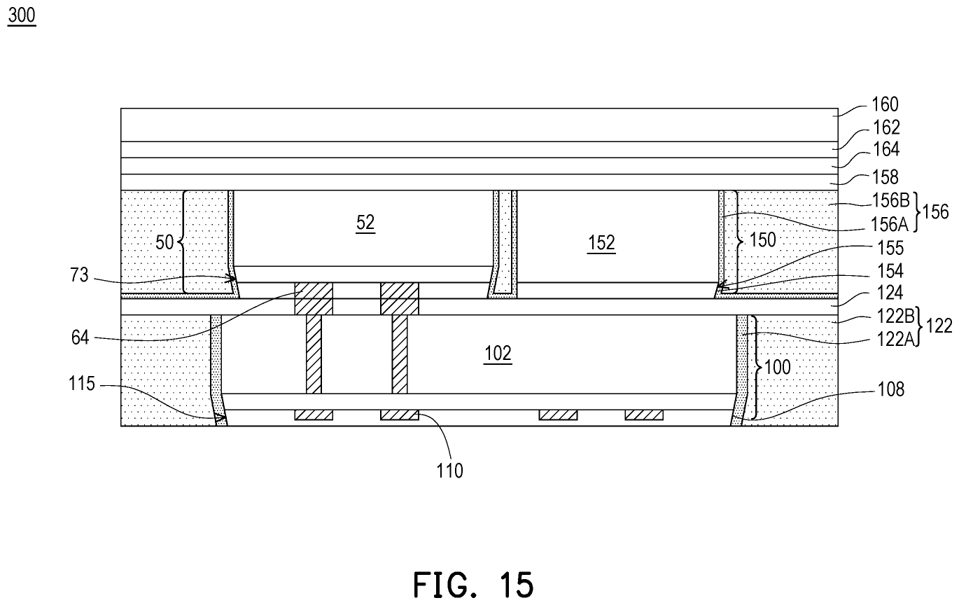

In FIG. 15, the carrier 116, the first bonding layer 118, the second bonding layer 120, the bonding layer 112 are removed. The carrier 116, the first bonding layer 118, the second bonding layer 120, the bonding layer 112 may be removed by a thinning process. A portion of the gap-fill dielectric 122 (e.g., a portion of the liner 122A on the second bonding layer 120, see FIG. 14) is also removed. The thinning process may be a CMP, a grinding process, an etch-back process, combinations thereof, or the like. After the thinning process, surfaces of the dielectric layer 108 and the gap-fill dielectric 122 may be substantially coplanar (within process variations). The illustrated embodiment wherein the portion of the liner 122A on the second bonding layer 120 is completely removed by the thinning process is an example. The portion of the liner 122A on the second bonding layer 120 may be partially removed by the thinning process and after the thinning process, surfaces of the dielectric layer 108 and the liner 122A may be substantially coplanar (within process variations).

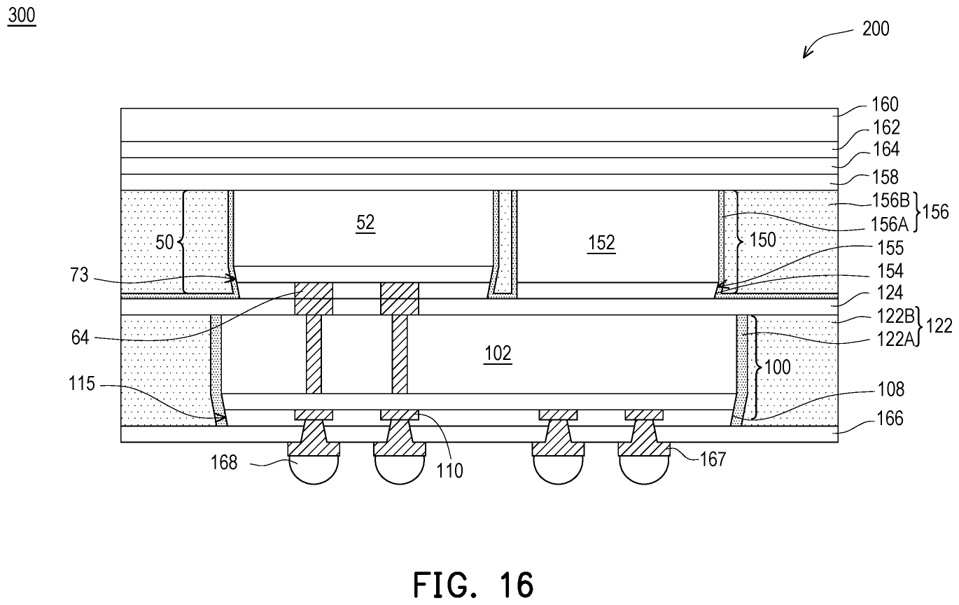

In FIG. 16, a dielectric layer 166 is formed on the dielectric layer 108 and the gap-fill dielectric 122 (e.g., the main filler 122B), under-bump metallizations (UBMs) 167 are formed on and through the dielectric layer 166, and electrical connectors 168 are formed on the UBMs 167. The dielectric layer 166 may comprise silicon dioxide, silicon nitride, or the like, and may be formed by a suitable deposition process such as CVD, ALD, or the like. The dielectric layer 166 may be a passivation layer. The UBMs 167 have bump portions on and extending along a surface of the dielectric layer 166, and have via portions extending through the dielectric layer 166 and the dielectric layer 108 to physically and electrically couple to the die connectors 110. As a result, the UBMs 167 are electrically coupled to the integrated circuit die 100.

As an example to form the UBMs 167, the dielectric layer 166 and the dielectric layer 108 are patterned to form openings exposing the underlying die connectors 110. The patterning may be done by an acceptable photolithography and etching processes, such as by forming a mask then performing an anisotropic etching. The mask is removed after the patterning. A seed layer (not separately illustrated) is formed on the dielectric layer 166, in the openings through the dielectric layer 166 and the dielectric layer 108, and on the exposed portions of the die connectors 110. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using a deposition process, such as physical vapor deposition (PVD) or the like. A photoresist is then formed and patterned on the seed layer. The photoresist may be formed by spin coating or the like and may be exposed to light for patterning. The pattern of the photoresist corresponds to the UBMs 167. The patterning forms openings through the photoresist to expose the seed layer. A conductive material is formed in the openings of the photoresist and on the exposed portions of the seed layer. The conductive material may be formed by plating, such as electroless plating or electroplating, or the like. The conductive material may comprise a metal or a metal alloy, such as copper, titanium, tungsten, aluminum, the like, or combinations thereof. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the UBMs 167.

Electrical connectors 168 are formed on the UBMs 167. The electrical connectors 168 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The electrical connectors 168 may include a conductive material such as solder, copper, aluminum, gold, nickel, silver, palladium, tin, the like, or a combination thereof. In some embodiments, the electrical connectors 168 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the electrical connectors 168 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. The structure shown in FIG. 16 may be referred to as wafer structure 200.

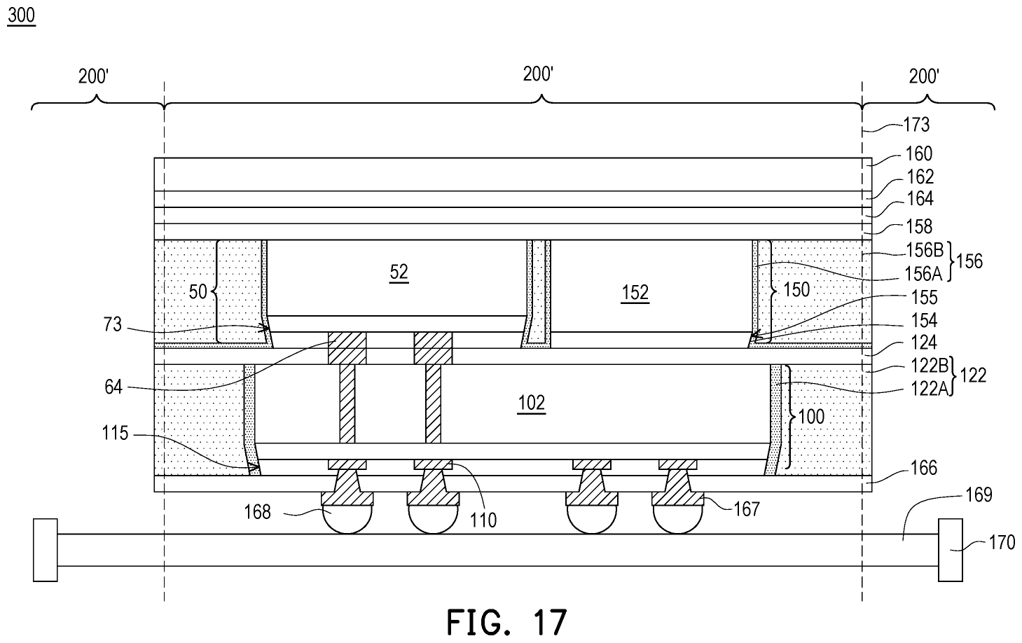

In FIG. 17, the wafer structure 200 is singulated. The wafer structure 200 is placed on a tape 169 supported by a frame 170. The wafer structure 200 is then singulated along scribe lines 173, so that the wafer structure 200 is separated into discrete integrated circuit package components 200′. The singulation process may include a sawing process, a laser cutting process, or the like. A cleaning process or rinsing process may be performed after the singulation process.

In FIGS. 18A through 18C, an integrated circuit package component 200′ is bonded to a package substrate 202 and an underfill 208 is formed between the integrated circuit package component 200′ and the package substrate 202. The resulting structure may be referred to as the integrated circuit package 300.

The package substrate 202 includes a substrate core 204 and bond pads 206 over the substrate core 204. The substrate core 204 may be formed of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core 204 may be an SOI substrate. Generally, an SOI substrate includes a layer of a semiconductor material such as epitaxial silicon, germanium, silicon germanium, SOI, SGOI, or combinations thereof. In some embodiments, the substrate core 402 is an insulating core formed of materials such as fiberglass reinforced resin, BT resin, other PCB materials or the like. Build up films such as ABF or other laminates may be used for substrate core 402.

The substrate core 402 may include active and passive devices (not separately illustrated). A wide variety of devices such as transistors, capacitors, resistors, combinations thereof, or the like may be used to generate the structural and functional requirements of the design for the device stack. The devices may be formed using any suitable methods. The substrate core 402 may also include metallization layers and vias, with the bond pads 206 being physically and electrically coupled to the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate core 204 is substantially free of active and passive devices.

During the bonding process the electrical connectors 168 are reflowed to bond the integrated circuit package component 200′ to the bond pads 206. The electrical connectors 168 electrically and physically couple the package substrate 202 to the integrated circuit package component 200′. In some embodiments, a solder resist (not separately illustrated) is formed on the substrate core 204. The electrical connectors 168 may be disposed in openings in the solder resist to be electrically and physically coupled to the bond pads 206. The solder resist may be used to protect areas of the substrate core 204 from external damage.

An underfill 208 is formed between the integrated circuit package component 200′ and the package substrate 202, surrounding the electrical connectors 168. The underfill 208 may reduce stress and protect the joints resulting from the reflowing of the electrical connectors 168. The underfill 208 may be formed by a capillary flow process after the integrated circuit package component 200′ is attached, or may be formed by a suitable deposition method before the integrated circuit package component 200′ is attached. The underfill 208 may be subsequently cured.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments may achieve advantages. The integrated circuit die 50, the integrated circuit die 100, and the inactive die 150 are singulated by a plasma dicing process prior to being packaged in the integrated circuit package 300. The plasma dicing process results in substantially vertical, smooth, continuous sidewalls on integrated circuit die 50, the integrated circuit die 100, and the inactive die 150, which reduces the risk of delamination of the gap-fill dielectric 122 around the integrated circuit die 100 as well as the risk of delamination of the gap-fill dielectric 156 around the integrated circuit die 50 and the inactive die 150 during the manufacturing and operation of the integrated circuit package 300, thereby improving the reliability of the integrated circuit package 300.

In an embodiment, a device includes a first integrated circuit die including a first substrate, wherein a first angle is between a first sidewall of the first substrate and a bottom surface of the first substrate; and a first interconnect structure on the bottom surface of the first substrate, wherein a second angle is between a first sidewall of the first interconnect structure and the bottom surface of the first substrate, and wherein the first angle is larger than the second angle; a first gap-fill dielectric layer around the first integrated circuit die; a second integrated circuit die including a second substrate; and a second interconnect structure on a bottom surface of the second substrate, wherein the first integrated circuit die is over a top surface of the second substrate; and a second gap-fill dielectric layer around the second integrated circuit die. In an embodiment, the first angle is a right angle. In an embodiment, the second angle is an acute angle and is larger than 85°. In an embodiment, the first integrated circuit die has a shape of an octagon in a top-down view. In an embodiment, an angle between two neighboring sides of the octagon is between 130° and 140°. In an embodiment, the first sidewall of the first interconnect structure is continuous and has a constant slope. In an embodiment, the device further includes a first dielectric layer, wherein the first dielectric layer extends between the first integrated circuit die and the second integrated circuit die, wherein the first dielectric layer extends between the first gap-fill dielectric layer and the second gap-fill dielectric layer, wherein the first dielectric layer is in contact with the top surface of the second substrate; and a first die connector extending through the first dielectric layer, wherein the first die connector electrically couples the first integrated circuit die and the second integrated circuit die.

In an embodiment, a device includes a first dielectric layer; a first die connector extending through the first dielectric layer; a first integrated circuit die on a first side of the first dielectric layer, the first integrated circuit die comprising: a first substrate; and a first interconnect structure on a first surface of the first substrate, wherein a first angle is between a chamfered sidewall of the first interconnect structure and the first surface of the first substrate, wherein a second angle is between a main sidewall of the first interconnect structure and the first surface of the first substrate, the second angle being larger than the first angle; a first gap-fill dielectric on the first side of the first dielectric layer and around the first integrated circuit die, wherein the first gap-fill dielectric extends along the chamfered sidewall and the main sidewall of the first interconnect structure; and a second integrated circuit die on a second side of the first dielectric layer, wherein the second integrated circuit die is electrically coupled to the first integrated circuit die by the first die connector, the second integrated circuit die including a second substrate; and a second interconnect structure on a first surface of the second substrate; and a conductive via extending through the second substrate and between the first die connector and the second interconnect structure. In an embodiment, the first angle is an acute angle and is larger than 85°. In an embodiment, the second angle is a right angle. In an embodiment, the chamfered sidewall of the first interconnect structure abuts the main sidewall of the first interconnect structure. In an embodiment, a third angle is between the chamfered sidewall of the first interconnect structure and the main sidewall of the first interconnect structure in a top-down view, the third angle being between 130° and 140°. In an embodiment, the main sidewall of the first interconnect structure has a larger length than the chamfered sidewall of the first interconnect structure in a top-down view.

In an embodiment, a method includes singulating a first integrated circuit die from a first wafer by plasma dicing, wherein the first integrated circuit die includes a first substrate, a first interconnect structure on the first substrate, a first dielectric layer on the first interconnect structure, and a first die connector in the first dielectric layer, the plasma dicing including exposing the first wafer to a first plasma, wherein the first plasma performs a first dry etching with a first degree of anisotropy, and wherein the first dry etching forms a first sidewall of the first interconnect structure; and exposing the first wafer to a second plasma, wherein the second plasma performs a second dry etching with a second degree of anisotropy, wherein the second degree of anisotropy is larger than the first degree of anisotropy, and wherein the second dry etching forms a second sidewall of the first substrate; forming a first gap-fill dielectric around the first integrated circuit die; depositing a second dielectric layer on the first gap-fill dielectric and the first integrated circuit die; forming a second die connector in the second dielectric layer; bonding a second integrated circuit die to the second dielectric layer and the second die connector; and forming a second gap-fill dielectric around the second integrated circuit die. In an embodiment, the first plasma and the second plasma are fluorine plasmas. In an embodiment, the first plasma and the second plasma are chlorine plasmas. In an embodiment, a first angle is between the first sidewall and a bottom surface of the first substrate, and wherein the first angle is an acute angle and is larger than 85°. In an embodiment, a second angle is between the second sidewall and the bottom surface of the first substrate, and wherein the second angle is larger than the first angle. In an embodiment, the first sidewall adjoins the second sidewall. In an embodiment, the first plasma is generated at a first power, the second plasma is generated at a second power, and the second power is larger than the first power.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a first integrated circuit die comprising:
a first substrate, wherein a first angle is between a first sidewall of the first substrate and a bottom surface of the first substrate; and
a first interconnect structure on the bottom surface of the first substrate, wherein a second angle is between a first sidewall of the first interconnect structure and the bottom surface of the first substrate, and wherein the first angle is larger than the second angle;
a first gap-fill dielectric layer around the first integrated circuit die;
a second integrated circuit die comprising:
a second substrate; and
a second interconnect structure on a bottom surface of the second substrate, wherein the first integrated circuit die is over a top surface of the second substrate; and
a second gap-fill dielectric layer around the second integrated circuit die.

2. The device of claim 1, wherein the first angle is a right angle.

3. The device of claim 1, wherein the second angle is an acute angle and is larger than 85°.

4. The device of claim 1, wherein the first integrated circuit die has a shape of an octagon in a top-down view.

5. The device of claim 4, wherein an angle between two neighboring sides of the octagon is between 130° and 140°.

6. The device of claim 1, wherein the first sidewall of the first interconnect structure is continuous and has a constant slope.

7. The device of claim 1, further comprising:
a first dielectric layer, wherein the first dielectric layer extends between the first integrated circuit die and the second integrated circuit die, wherein the first dielectric layer extends between the first gap-fill dielectric layer and the second gap-fill dielectric layer, wherein the first dielectric layer is in contact with the top surface of the second substrate; and
a first die connector extending through the first dielectric layer, wherein the first die connector electrically couples the first integrated circuit die and the second integrated circuit die.

8. A device comprising:
a first dielectric layer;
a first die connector extending through the first dielectric layer;
a first integrated circuit die on a first side of the first dielectric layer, the first integrated circuit die comprising:
a first substrate; and
a first interconnect structure on a first surface of the first substrate, wherein a first angle is between a chamfered sidewall of the first interconnect structure and the first surface of the first substrate, wherein a second angle is between a main sidewall of the first interconnect structure and the first surface of the first substrate, the second angle being larger than the first angle;
a first gap-fill dielectric on the first side of the first dielectric layer and around the first integrated circuit die, wherein the first gap-fill dielectric extends along the chamfered sidewall and the main sidewall of the first interconnect structure; and
a second integrated circuit die on a second side of the first dielectric layer, wherein the second integrated circuit die is electrically coupled to the first integrated circuit die by the first die connector, the second integrated circuit die comprising:
a second substrate; and
a second interconnect structure on a first surface of the second substrate; and
a conductive via extending through the second substrate and between the first die connector and the second interconnect structure.

9. The device of claim 8, wherein the first angle is an acute angle and is larger than 85°.

10. The device of claim 8, wherein the second angle is a right angle.

11. The device of claim 8, wherein the chamfered sidewall of the first interconnect structure abuts the main sidewall of the first interconnect structure.

12. The device of claim 8, wherein a third angle is between the chamfered sidewall of the first interconnect structure and the main sidewall of the first interconnect structure in a top-down view, the third angle being between 130° and 140°.

13. The device of claim 8, wherein the main sidewall of the first interconnect structure has a larger length than the chamfered sidewall of the first interconnect structure in a top-down view.

14. A method comprising:
singulating a first integrated circuit die from a first wafer by plasma dicing, wherein the first integrated circuit die comprises a first substrate, a first interconnect structure on the first substrate, a first dielectric layer on the first interconnect structure, and a first die connector in the first dielectric layer, the plasma dicing comprising:
exposing the first wafer to a first plasma, wherein the first plasma performs a first dry etching with a first degree of anisotropy, and wherein the first dry etching forms a first sidewall of the first interconnect structure; and
exposing the first wafer to a second plasma, wherein the second plasma performs a second dry etching with a second degree of anisotropy, wherein the second degree of anisotropy is larger than the first degree of anisotropy, and wherein the second dry etching forms a second sidewall of the first substrate;
forming a first gap-fill dielectric around the first integrated circuit die;
depositing a second dielectric layer on the first gap-fill dielectric and the first integrated circuit die;
forming a second die connector in the second dielectric layer;
bonding a second integrated circuit die to the second dielectric layer and the second die connector; and
forming a second gap-fill dielectric around the second integrated circuit die.

15. The method of claim 14, wherein the first plasma and the second plasma are fluorine plasmas.

16. The method of claim 14, wherein the first plasma and the second plasma are chlorine plasmas.

17. The method of claim 14, wherein a first angle is between the first sidewall and a bottom surface of the first substrate, and wherein the first angle is an acute angle and is larger than 85°.

18. The method of claim 17, wherein a second angle is between the second sidewall and the bottom surface of the first substrate, and wherein the second angle is larger than the first angle.

19. The method of claim 14, wherein the first sidewall adjoins the second sidewall.

20. The method of claim 14, wherein the first plasma is generated at a first power, the second plasma is generated at a second power, and the second power is larger than the first power.
